(19) United States
(12) Patent Application Publication
(10) Pub. No.: US 2013/0153645 A1
(43) Pub. Date: Jun. 20, 2013

(54) Process for Hybrid Integration of Focal Plane Arrays

(71) Applicant: Princeton Lightwave, Inc., Cranbury, NJ (US)

(72) Inventors: Mark Andrew Owens, Doylestown, PA (US); Sabbir Sajjad Rangwala, West Windsor, NJ (US); Bora Muammer Onat, Robbinsville, NJ (US); Domenick Salvemini, North Plainfield, NJ (US)

(73) Assignee: PRINCETON LIGHTWAVE, INC., Cranbury, NJ (US)

(21) Appl. No.: 13/680,825

(22) Filed: Nov. 19, 2012

Related U.S. Application Data
(60) Provisional application No. 61/561,151, filed on Nov. 17, 2011.

(51) Int. Cl. H01L 23/00

(52) U.S. Cl. CPC H01L 24/81
USPC 228/180.22

(57) ABSTRACT

A method for aligning a first substrate relative to a second substrate by enabling reflow of low-melting-temperature solder bumps is disclosed. Reflow of the solder bumps induces a force that moves one substrate relative to the other to improve alignment accuracy between bond pads located on each substrate. The method further enables reduction of surface oxide on the solder bumps that would otherwise inhibit reliable solder joint formation.

### CROSS REFERENCE TO RELATED APPLICATIONS

This case claims priority of U.S. Provisional Patent Application U.S. 61/561,151, which was filed on Nov. 17, 2011 (Attorney Docket: 293-028PROV), and which is incorporated herein by reference.

### STATEMENT REGARDING FEDERALLY SPONSORED RESEARCH

This invention was made with Government support under contract FA8650-10-1727 awarded by the United States Air Force. The Government has certain rights in the invention.

### FIELD OF THE INVENTION

The present invention relates to focal plane arrays in general, and, more particularly, to hybrid integration of focal plane arrays and read-out integrated circuits.

### BACKGROUND OF THE INVENTION

Hybrid integration of two substrates using flip-chip solder-bump bonding has been a mainstay of the semiconductor industry for decades. In such integration, a first substrate comprising a first type of semiconductor device flipped over and attached to a second substrate by means of solder bumps that interpose the two substrates. Typically, these solder bumps enable physical and electrical interconnection between the substrates. Common solders used for such solder bumps include lead-tin compositions, gold-tin, high-tin eutectics, and the like.

Unfortunately, conventional flip-chip solder-bump bonding has several drawbacks for many applications—especially the integration of optical devices, such as a focal-plane array (FPA) onto its control circuit, such as a Read-Out Integrated Circuit (ROIC).

First, the alignment accuracy that can be attained with a conventional die bonder is limited to a few microns, which is insufficient for integrating a highly dense, small pixel-element FPA onto an ROIC. Second, many commonly used solders have a melting point that is higher than the thermal budget of either the FPA or the ROIC. This is particularly problematic for single-photon detection devices, which include very shallow diffusion regions.

A method that enables hybrid integration of two substrates without some of the costs and disadvantages of the prior art is desirable.

### SUMMARY OF THE INVENTION

The present invention enables hybrid integration of an FPA and ROIC with high placement precision using solder bumps that include indium. Embodiments of the present invention are particularly well suited for integration of infrared focal-plane arrays and ROICs.

An embodiment of the present invention is a method wherein an FPA and an ROIC are brought into rough alignment within a semi-enclosed chamber. The FPA includes a first arrangement of bond pads and the ROIC includes a second arrangement of bond pads that corresponds with the first arrangement. One or both of the first and second plurality of bond pads include solder bumps comprising indium. While the FPA and ROIC are within the chamber, surface oxide on the solder bumps is desorbed or otherwise reduced to leave surfaces suitable for forming high-quality bonds. In some embodiments, desorption is effected by heating the solder bumps while they are exposed to a hydrogen-rich gas environment. In some embodiments, the hydrogen-rich gas is heated as it is introduced to the chamber. After reduction of the surface oxide, the FPA and ROIC are brought into physical contact such that the first plurality of bond pads and second plurality of bond pads are physically coupled via solder bumps. The solder bumps are then heated so that they melt sufficiently to enable them to induce self-alignment of the first plurality of bond pads and second plurality of bond pads. Self-alignment occurs due to the tendency for the solder bumps to reduce their surface energy once they have melted.

An embodiment of the present invention comprises a method for joining a first substrate having a first plurality of bonding sites arranged in a first arrangement and a second substrate having a second plurality of bonding sites arranged in a second arrangement that is complimentary with the first arrangement, the method comprising: positioning the first substrate with respect to the second substrate, wherein one or both of the first plurality of bonding sites and second plurality of bonding sites comprises solder bumps that include solder comprising indium; reducing a surface oxide on the surface of the solder bumps; arranging the first substrate and second substrate such that each of the first plurality of bonding sites and a corresponding one of the second plurality of bonding sites is physically coupled via a solder bump; reflowing the solder bumps; and enabling a reduction of the surface energy of the solder bumps.

### BRIEF DESCRIPTION OF THE DRAWINGS

FIG. 1 depicts a schematic drawing of a cross-sectional view of an integrated focal plane array and read-out integrated circuit in accordance with an illustrative embodiment of the present invention.

FIG. 2 depicts a schematic drawing of a cross-sectional view of a system for enabling hybrid integration of a focal-plane array and a read-out integrated circuit in accordance with the illustrative embodiment of the present invention.

FIG. 3 depicts operations of a method for integrating two substrates in accordance with the illustrative embodiment of the present invention.

FIGS. 4A-D depict schematic drawings of cross-sectional views of substrates 102 and 104 at different points in a hybrid integration process in accordance with the illustrative embodiment of the present invention.

FIGS. 5A and 5B depict alignment features for facilitating alignment of solder bumps, before and after mating, respectively, in accordance with an alternative embodiment of the present invention.

### DETAILED DESCRIPTION

It is an aspect of the present invention that solder-reflow after flip-chip solder-bump bonding can be used to improve the alignment accuracy between two substrates. Since most solders have a melting point that is higher than the thermal budget of a typical PFA, however, it is a further aspect of the present invention to use indium-based solder bumps (including pure indium), which have a low melting point. It is well known, however, that indium-base solders quickly develop a surface oxide that inhibits their use in bump bonding applications. It is a further aspect of the present invention, therefore, that reduction of the surface oxide on indium-based solder bumps is done while the solder bumps are contained within a chamber having a controllable environment. A pick-and-place tool having access into the chamber is then used to roughly align and bond the two substrates once the surface oxide is sufficiently reduced. After bonding, the two substrates are heated to melt the indium solder enabling them to reflow in a manner that reduces their surface energy by substantially minimizing their surface area. The solder bumps are provided in an arrangement that affords sufficient force during solder reflow that the solder bumps can induce relative motion between the two substrates, thus resulting in more precise alignment.

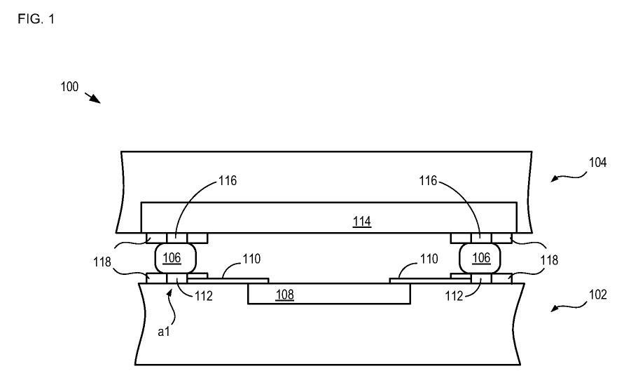

FIG. 1 depicts a schematic drawing of a cross-sectional view of an integrated focal plane array and read-integrated circuit in accordance with an illustrative embodiment of the present invention. Device 100 comprises substrate 102, substrate 104, and solder joints 106.

Substrate 102 is a portion of a read-out integrated circuit chip that includes a plurality of circuits 108, interconnects 110, and bond pads 112. The plurality of circuits 108 collectively defines a read-out integrated circuit.

Circuit 108 is a conventional read-out circuit for interfacing to a photoreceptor element of a focal plane array. Circuit 108 is one of a plurality of such circuits that collectively define a read-out integrated circuit.

Interconnects 110 are conventional electrically conductive traces that electrically couple circuit 108 with bond pads 112.

Bond pads 112 are conventional bond pads suitable for enabling solder-bump bonding of the ROIC with a focal-plane array.

Substrate 104 is a portion of a focal-plane array chip that comprises a plurality of avalanche photodiodes 114, each electrically coupled with a pair of bond pads 116. The plurality of avalanche photodiodes 114 collectively defines a focal-plane array.

Bond pads 112 are arranged in a first arrangement on substrate 102. In similar fashion, bond pads 116 are arranged in a second arrangement on substrate 104. The first and second arrangements of bond pads are complimentary such that when substrates 102 and 104 are positioned face-to-face, the layouts of the two arrangements of bond pads substantially match.

Each of bond pads 112 and 116 includes a surface that wets the material of solder joints 106. Each of bond pads 112 and 116 has a center region having surface area, a1, that is exposed, while layer 118 covers the remaining area of the bond pad as well as regions of substrate 102 and 104 that surround these center regions. Layer 118 comprises a material, such as silicon nitride, that does not wet the material of solder joints 106.

Solder joints 106 are solder bumps of substantially pure indium. Indium is preferably used for solder joints 106 due to its low melting point. In the prior art, however, indium is not typically used due to the fact that it readily forms a surface oxide that can impair its utility as a bonding material. This is particularly true in a production environment, where reliability and repeatability of solder joint characteristics are paramount. In some embodiments, solder joints 106 comprise a solder other than pure indium.

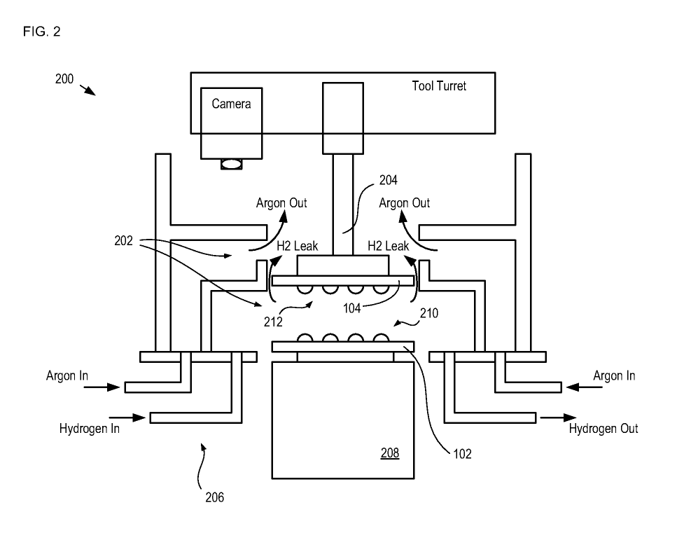

FIG. 2 depicts a schematic drawing of a cross-sectional view of a system for enabling hybrid integration of a focal-plane array and a read-out integrated circuit in accordance with the illustrative embodiment of the present invention. System 200 comprises chamber 202, tool 204, gas system 206, and chuck 208.

Chamber 202 is a substantially enclosed chamber suitable for controlling the environment that surrounds substrates 102 and 104. Substrate 102 comprises solder bumps 210 and substrate 104 comprises solder bumps 212. Solder bumps 210 are arranged in a first arrangement on the surface of substrate 102. Solder bumps 212 are arranged in a second arrangement on the surface of substrate 104, wherein the first and second arrangements are complimentary such that they substantially match when the substrates are positioned in a face-to-face orientation. In some embodiments, only one of substrates 102 and 104 comprises solder bumps.

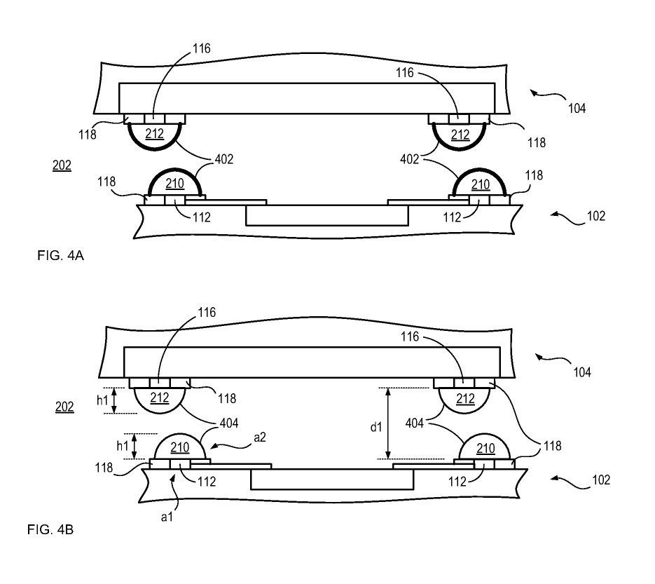

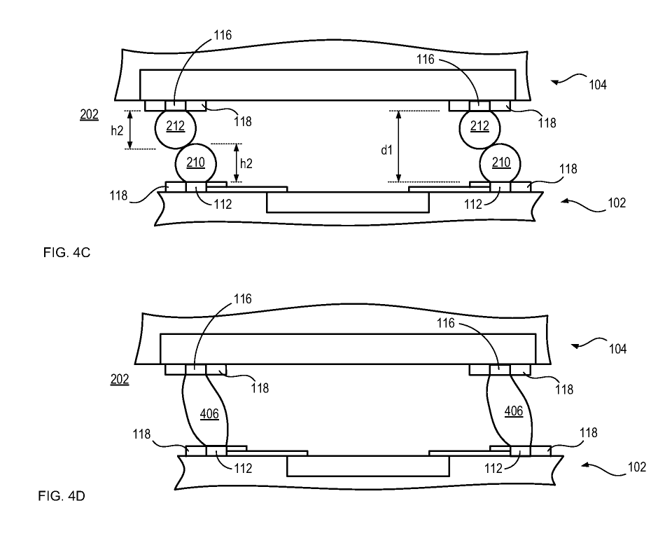

By controlling the environment within chamber 202, desorption of surface oxide on the solder bumps can be effected, as described below and with respect to FIGS. 4 and 4A-D. In some embodiments, chamber 202 includes ports for enabling gas to escape the chamber, for example, during an oxygen purge when oxygen is displaced by hydrogen pumped into the chamber.

Tool 204 is a conventional pick-and-place tool suitable for controlling the relative position between substrates 102 and 104. Tool 204 controllable holds and releases substrate 104 and typically has up to six-axis control capability.

Gas system 206 is a system for controllably introducing one or more gasses into chamber 202. In the illustrative embodiment, gas system 206 is configured to introduce argon and hydrogen into chamber 202; however, it will be clear to one skilled in the art, after reading this Specification, how to specify, make, and use alternative embodiments of the present invention wherein gas system 206 introduces one or more suitable gasses other than argon and hydrogen into chamber 202. Gasses suitable for use in embodiments in accordance with the present invention include, without limitation, hydrogen, argon, nitrogen, forming gas, sulfur hexafluoride, chlorine-containing gasses, and the like. In some embodiments, gas system 206 includes gas-heating apparatus for controlling the temperature of a gas that is being introduced into chamber 202.

Chuck 208 is a conventional vacuum chuck for securing a substrate. In some embodiments, chuck 208 can also control the temperature of a substrate mounted in the chuck and/or an electrical bias on the substrate.

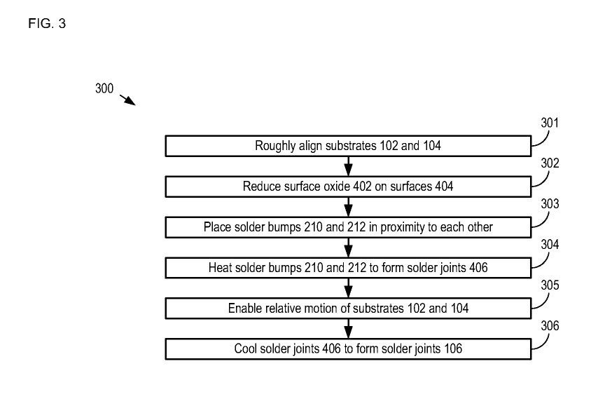

FIG. 3 depicts operations of a method for integrating two substrates in accordance with the illustrative embodiment of the present invention. FIG. 3 is described with continuing reference to FIGS. 1 and 2 and FIGS. 4A-D. Method 300 begins with operation 301, wherein substrates 102 and 104 are put into rough alignment.

FIGS. 4A-D depict schematic drawings of cross-sectional views of substrates 102 and 104 at different points in a hybrid integration process in accordance with the illustrative embodiment of the present invention.

FIG. 4A depicts substrates 102 and 104 while positioned in rough alignment with one another but while their respective solder bumps are not in contact. Substrates 102 and 104 are depicted while enclosed by chamber 202. Rough alignment can be attained with conventional pick-and-place tools, such as tool 204. Examples of suitable pick-and-place tools include the Palomar 3800 Die Bonder, etc.

In the illustrative embodiment, each of solder bumps 210 and 212 is disposed on their respective bond pad such that its extent exceeds the perimeter of the bond pad. In other words, the cross-sectional area, a2, of each of solder bumps 210 and 212 where it meets its respective bond pad is greater than the surface area of the bond pad, a1. It should be noted that solder bumps 210 and 212 are depicted as hemispheres. In some embodiments, at least one of solder bumps 210 and 212 has a shape other than

At operation 302, surface oxide 402 is reduced on surface 404 of solder bumps 210 and 212. Surface oxide 402 is reduced by first purging chamber 202 of oxygen and filling chamber 202 with heated hydrogen gas. Elevating the temperature of solder bumps 210 and 212 in the presence of hydrogen enables the reduction of surface oxide 402.

Once surface 404 is substantially oxide-free, the temperature of the hydrogen environment is reduced but the environment in chamber 202 remains substantially oxygen-free. After reduction of surface oxide 402, each of solder bumps 210 and 212 projects above the height of its respective bond pad by height h1.

FIG. 4B depicts substrates 102 and 104 while positioned in rough alignment with one another and after the reduction of surface oxide 402, but while solder bumps 210 and 212 are not in contact.

At operation 303, solder bumps 210 and 212 are brought into close proximity, but not into contact, by tool 204. This results in a separation distance between bond pads 116 and 118 of distance d1.

In some embodiments, alignment features are included on each of substrates 102 and 104 to facilitate the rough alignment of solder bumps 210 and 212 as well as establish a separation distance between substrates 102 and 104 after operation 303.

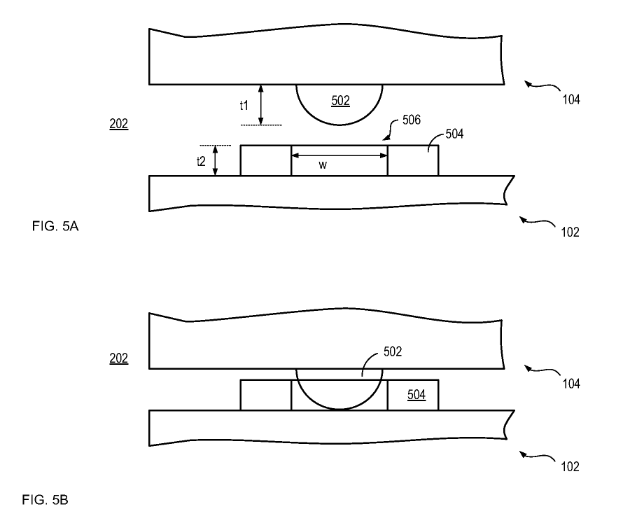

FIGS. 5A and 5B depict alignment features for facilitating alignment of solder bumps in accordance with an alternative embodiment of the present invention. Alignment feature 500 comprises probe 502 and receiver 504. FIG. 5A depicts probe 502 and receiver 504 prior to engagement. FIG. 5B depicts probe 502 and receiver 504 after engagement.

Probe 502 is a substantially hemispherically shaped projection that is located on substrate 102 at a point outside the arrangement of solder bumps 210.

Receiver 504 is a substantially circular annulus that is located outside the field of solder bumps 212 on substrate 104.

Typically, at least three probes and matching receivers are included on substrates 102 and 104 to ensure good lateral and rotational alignment. In some embodiments, probes 502 are located on substrate 104 and receivers 504 are located on substrate 102. In some embodiments, at least one of probe 502 and receiver 504 is located within the arrangement of solder bumps on its respective substrate.

At least one of probe 502 and receiver 504 typically comprises a material that can be shaped in three-dimensions and does not exhibit excessive friction. Suitable materials for use in probe 502 and receiver 504 include, without limitation: cyclotene advanced electronic resins, such as benzocyclobutene (BCB); SU-8; polyimides; photoresists; dielectrics, such as nitrides, oxide, oxynitrides, etc.; ceramics; metals, solders; and the like.

In some embodiments, at least one of probe 502 and receiver 504 is formed as a recess in the surface of its respective substrate via an etch process.

In operation, the thicknesses, t1 and t2, of probe 502 and receiver 504, respectively, as well as the width, w, of opening 506 in receiver 504, are selected to provide good lateral and rotational alignment and to establish a desired separation between substrates 102 and 104 at the end of operation 303.

Returning now to FIGS. 3 and 4A-D, during operation 303, tool 204 roughly aligns substrate 104 to substrate 102 such that d1 is greater than the combined height of solder bumps 210 and 212 (i.e., d1>2h1). Currently available production-scale aligner-bonders can typically attain lateral alignment accuracy of approximately 10 microns. Probe 502 and receiver 504 are sized such that this level of accuracy enables their engagement, which then improves the lateral precision of the alignment between the substrates to within a few microns. Accurate alignment of solder bumps 210 and 212 within a few microns is sufficient to enable reflow of the solder bumps to bring bond pads 112 and 116 into fine alignment, as described below.

At operation 304, solder bumps 210 and 212 are heated above their melting point. Because the material of solder bumps 210 and 212 does not wet to layer 118, it exhibits a very high contact angle where the solder bump material meets their respective bond pads. In some cases, for example, the solder bumps form substantially spherical shapes that project outward from their respective bond pads. As a result, the projection of bond pads 210 and 212 above their respective bond pads increases to height h2, which is greater than half the distance d1. Due to this increase in their height, each of solder bumps 210 comes into physical contact with its corresponding solder bump 212. During operation 304, heated hydrogen gas typically flows into chamber 202.

FIG. 4C depicts substrates 102 and 104 after solder bumps 210 and 212 are in physical contact within chamber 202.

At operation 305, substrate 104 is released by tool 204. This enables substantially unconstrained relative motion between substrates 102 and 104. In some embodiments, in order to improve the oxygen purge from chamber 202, a vented cover is installed to block the access port through which tool 204 had access to substrate 104.

During operation 305, each contacting pair of solder bumps 210 and 212 is kept at an elevated temperature for a dwell time sufficient to enable them merge into a single liquid solder joint 406.

FIG. 4D depicts substrates 102 and 104 after the formation of solder joints 406.

The temperature of solder joints 406 is maintained at an elevated temperature to enable them reduce their surface energy by substantially minimizing their surface area. The reduction of surface energy of solder joints 406 generates enough force to move substrate 104 relative to substrate 102 thereby improving the alignment of bond pads 116 and 112.

At operation 306, once bond pads 116 and 112 are suitably aligned, the temperature of chuck 208 is reduced, which reduces the temperature of solder joints 406 enabling them to solidify into solder joints 106, as depicted in FIG. 1.

It is to be understood that the disclosure teaches just one example of the illustrative embodiment and that many variations of the invention can easily be devised by those skilled in the art after reading this disclosure and that the scope of the present invention is to be determined by the following claims.

What is claimed is:

1. A method for joining a first substrate and a second substrate, the method comprising:
providing the first substrate, the first substrate including a first plurality of bonding sites, each having one of a first plurality of solder bumps;
providing the second substrate, the second substrate including a second plurality of bonding sites, each having one of a second plurality of solder bumps;
reducing a surface oxide on each of the first plurality of solder bumps and second plurality of solder bumps;
reflowing the first plurality of solder bumps and second plurality of solder bumps;
enabling physical contact between the first plurality of solder bumps and the second plurality of solder bumps to form a first plurality of solder joints; and
enabling a reduction of the surface energy of each of the first plurality of solder joints.

2. The method of claim 1 wherein physical contact between the first plurality of solder bumps and second plurality of solder bumps is enabled by operations comprising:
separating the first plurality of bonding sites and second plurality of bonding sites by a first separation distance, d1; and
enabling each of the first plurality of solder bumps and second plurality of solder bumps to project above their respective bonding sites by a height, h1, where h1≧0.5*d1.

3. The method of claim 2 wherein the projection of each of the first plurality of solder bumps and second plurality of solder bumps above their respective bonding sites by height h1 is enabled by operations comprising:
providing each of the first plurality of bonding sites and second plurality of bonding sites with a bond pad having a surface area, a1, each bond pad being surrounded by a first material;
providing each of the first plurality of solder bumps and second plurality of solder bumps such that each solder bump has a cross-sectional area, a2, at its respective bond pad, where a2>a1, wherein each of the first plurality of solder bumps and second plurality of solder bumps comprises a second material that is substantially non-wetting with the first material; and
melting each of the first plurality of solder bumps and second plurality of solder bumps.

4. The method of claim 1 wherein the surface oxide is reduced while the first substrate and second substrate are located in a first chamber.

5. The method of claim 4 wherein the reduction of the surface energy is enabled while the first substrate and second substrate are located in the first chamber.

6. The method of claim 1 further comprising positioning the first substrate and second substrate in a first chamber, wherein the surface oxide is reduced while the first substrate and second substrate remain in the first chamber, and wherein physical contact between the first plurality of solder bumps and the second plurality of solder bumps is enabled while the first substrate and second substrate remain in the first chamber, and further wherein the first plurality of solder bumps and the second plurality of solder bumps are reflowed while the first substrate and second substrate remain in the first chamber.

7. The method of claim 1 wherein the surface oxide is reduced by heating the first plurality of solder bumps and the second plurality of solder bumps in the presence of hydrogen.

8. The method of claim 1 wherein the first substrate is provided such that it further comprises a focal-plane array and the second substrate is provided such that it further comprises a read-out integrated circuit.

9. The method of claim 1 wherein the first substrate is provided such that each of the first plurality of solder bumps consists of indium, and wherein the second substrate is provided such that each of the second plurality of solder bumps consists of indium.

10. A method for joining a first substrate having a first plurality of bonding sites arranged in a first arrangement and a second substrate having a second plurality of bonding sites arranged in a second arrangement that is complimentary with the first arrangement, each of the firs plurality of bonding sites and the second plurality of bonding sites having a solder bump disposed on it, the method comprising:
positioning the first substrate and second substrate in a first chamber;
reducing a surface oxide of the solder bumps;
arranging the first substrate and second substrate such that each of the first plurality of bonding sites and a corresponding one of the second plurality of bonding sites is physically coupled via a solder joint comprising two solder bumps;
enabling relative motion of the first substrate and second substrate; and
enabling a reduction of the surface energy of the solder joints.

11. The method of claim 10 further comprising purging oxygen from the first chamber.

12. The method of claim 11 further comprising introducing a first gas to the first chamber, the first gas being operable for enabling reduction of the surface oxide of the solder bumps.

13. The method of claim 12 further comprising heating the first gas.

14. The method of claim 12 wherein the first gas comprises hydrogen.

15. The method of claim 12 wherein the first gas comprises a gas selected from the group consisting of argon, nitrogen, forming gas, sulfur hexafluoride, and chlorine-containing gas.

16. The method of claim 10 further comprising heating the solder bumps during reduction of the surface oxide.

17. The method of claim 10 further comprising exposing the solder bumps to hydrogen during reduction of the surface oxide.

18. The method of claim 10 further comprising exposing the solder bumps to hydrogen and heating the solder bumps during reduction of the surface oxide.

19. The method of claim 10 wherein physical coupling of the first plurality of bonding sites and second plurality of bonding sites is enabled by operations comprising:
providing the first substrate such that each of the first plurality of bonding sites has a bond pad having a surface area, a1, that is surrounded by a first material;
providing the second substrate such that each of the second plurality of bonding sites has a bond pad having a surface area, a1, that is surrounded by the first material;
providing each of the solder bumps such that it has a cross-sectional area, a2, at its respective bond pad, where a2>a1, wherein each of the solder bumps comprises a second material that is substantially non-wetting with the first material;
positioning the first substrate and second substrate such that the first plurality of bonding sites and second plurality of bonding sites are separated by a first separation distance, d1; and
melting each of the solder bumps such that it projects above its respective bonding site by a height, h1, that is greater than or equal to 0.5*d1.
